(19) United States
(12) Patent Application Publication
(10) Pub. No.: US 2007/0152330 A1
(43) Pub. Date: Jul. 5, 2007

(54) Package structure and manufacturing method thereof

(75) Inventor: Sung-Fei Wang, Kaohsiung (TW)

Correspondence Address: BIRCH STEWART KOLASCH & BIRCH, PO BOX 747, FALLS CHURCH, VA, 22040-0747, US

(73) Assignee: Advanced Semiconductor Engineering, Inc.

(21) Appl. No.: 11/485,964

(22) Filed: Jul. 14, 2006

(30) Foreign Application Priority Data
Jan. 2, 2006 (TW) 095100113

(51) Int. Cl. H01L 23/48; H01L 21/44

(52) U.S. Cl. 257/737; 438/613; 257/E23.021; 257/778

(57) ABSTRACT

A package structure and a manufacturing method thereof are provided. The package structure includes a chip, a substrate and a solder. The chip includes a bump disposed on the surface of the chip. The substrate includes a pad and a solder resistor layer. The pad is disposed on the surface of the substrate and corresponds to the bump. The solder resistor layer is disposed on the surface of the substrate. The solder resistor layer has an opening for exposing the pad. The ratio of the width of the opening to the diameter of the bump ranges between 1 and 1.5. The solder is disposed in the opening and around the bump. The solder, the bump and the pad are welded together for electrically connecting the chip and the substrate.

This application claims the benefit of Taiwan application Ser. No. 095100113, filed Jan. 2, 2006, the subject matter of which is incorporated herein by reference.

### BACKGROUND OF THE INVENTION

1. Field of the Invention

The invention relates in general to a package structure, and more particularly to a package structure capable of fastening the contact point between the chip and the substrate.

1. Description of the Related Art

As there are new electronic products appearing in the market, the electronic products are equipped with more diversified functions. Take the packaging technology of the package structure of the electronic products for example. For enabling the products to have better efficiency and smaller packaged size, the flip chip packaging technology is commonly adopted.

Referring to FIG. 1 and FIG. 2. FIG. 1 is a bottom view of a chip. FIG. 2 is a side view of a conventional package structure. In FIG. 1, a number of bumps 120 are formed on the surface of the chip 100. In FIG. 2, the package structure 150 includes a substrate 110 and a chip 100. The chip 100 is bonded on the substrate 110 via flip chip bonding.

Referring to FIG. 3, a partial enlargement of the package structure of FIG. 2 is shown. In the package structure 150, a solder resistor layer 130 is coated on the substrate 110. The solder resistor layer 130 has an opening 132. A solder 140 is disposed in the opening 132. The solder 140 and the bump 120 are soldered together to form a contact point for electrically connecting the chip 100 and the substrate 110.

However, the coefficient of thermal expansion (CTE) of chip 100 is not the same with the coefficient of thermal expansion of the substrate 110. When the chip 100 is operating under an environment where temperature is changeable, thermal stress will be concentrated on the bump 120 disposed on the chip 100 due to the difference in the coefficient of thermal expansion. Consequently, the contact point between the bump 120 and the substrate 110 is damaged and malfunctioned.

As shown in FIG. 2, the bumps 120 are more intensively distributed inside the package structure 150 than outside the package structure 150. The stress is easily concentrated at the bump 120 disposed in the central region, causing damage to the contact point between the bump 120 and the substrate 110. Therefore, how to provide a package structure having a firm contact point has become an imminent problem to be resolved.

### SUMMARY OF THE INVENTION

It is therefore an object of the invention to provide a package structure. In the solder resistor layer, the ratio of the width of the opening to the diameter of the bump ranges between 1 and 1.5. The opening is able to accommodate more amount of solder. The solder is disposed on the lateral side of the bump and covers up the bump, such that the solder and the bump form a cylinder structure, a chamfered structure or a structure of other shapes so as to enhance the bond between the bump and the substrate, prevent the contact point between the bump and the substrate from being damaged by the stress and prolong the lifespan of the package structure.

The invention achieves the above-identified object by providing a package structure including a chip, a substrate, and a plurality of solders. The chip includes a number of first bumps and second bumps. The first bumps are distributed around the surface of the chip. The second bumps are distributed at the central region of the surface of the chip. The first bumps are more intensively distributed than the second bumps. The substrate includes a number of first pads and second pads, and a solder resistor layer. The first pads are disposed on the surface of the substrate and correspond to the first bumps. The second pads are disposed on the surface of the substrate and correspond to the second bumps. The solder resistor layer is disposed on the surface of the substrate. The solder resistor layer has a number of first openings and second openings. The first openings are for exposing the first pads. The second openings are for exposing the second pads. The ratios of the width of the second openings to the diameter of the second bumps range between 1 and 1.5. The solders are disposed in the first openings and the second openings. The solder, the first bump and the first pad corresponding to the first bump are welded together. The solder, the second bump and the second pad corresponding to the second bump are welded together for electrically connecting the chip and the substrate.

The invention further achieves the above-identified object by providing a package structure including a chip, a substrate and a solder. The chip includes a bump disposed on the surface of the chip. The substrate includes a pad and a solder resistor layer. The pad is disposed on the surface of the substrate and corresponds to the bump. The solder resistor layer is disposed on the surface of the substrate. The solder resistor layer has an opening for exposing the pad. The ratio of the width of the opening to the diameter of the bump ranges between 1 and 1.5. The solder is disposed in the opening and around the bump. The solder, the bump and the pad are welded together for electrically connecting the chip and the substrate.

The invention further achieves the above-identified object by providing a method of manufacturing a package structure. The method includes the following steps. At first, a chip including a bump is provided. Next, a substrate including a pad and a solder resistor layer is provided. The pad corresponds to the bump and is disposed on the surface of the substrate. The solder resistor layer is disposed on the surface of the substrate. The solder resistor layer has an opening for exposing the pad. The ratio of the width of the opening to the diameter of the bump ranges between 1 and 1.5. A solder is disposed in the opening. Then, the chip is placed on the substrate, wherein the bump corresponds to the opening. Next, the chip and the substrate are reflown to solder the bump, the solder and the pad together.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 is a bottom view of a chip;

FIG. 2 is a side view of a conventional package structure;

FIG. 3 is a partial enlargement of the package structure of FIG. 2;

FIG. 4A is a side view of a package structure according to a first preferred embodiment of the invention;

FIG. 4B is a bottom view of a chip of FIG. 4A;

FIG. 5A is a partial enlargement of a second bump of FIG. 4A;

FIG. 5B illustrates the ratio of the width w to the diameter d of FIG. 5A is 1;

FIG. 6 illustrates the ratio of the width of the first opening to the diameter of the first bump of FIG. 4A is 1;

FIG. 7 is a flowchart of a method of manufacturing a package structure according to a first preferred embodiment of the invention; and

FIG. 8 is a side view of a package structure according to a second preferred embodiment of the invention.

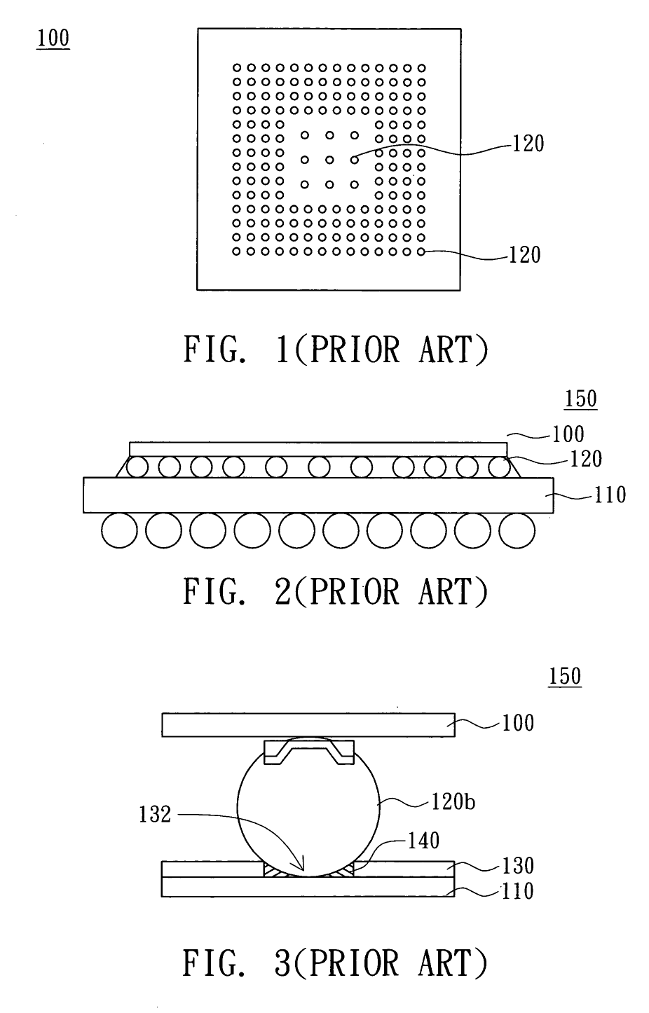

### DETAILED DESCRIPTION OF THE INVENTION

### First Embodiment

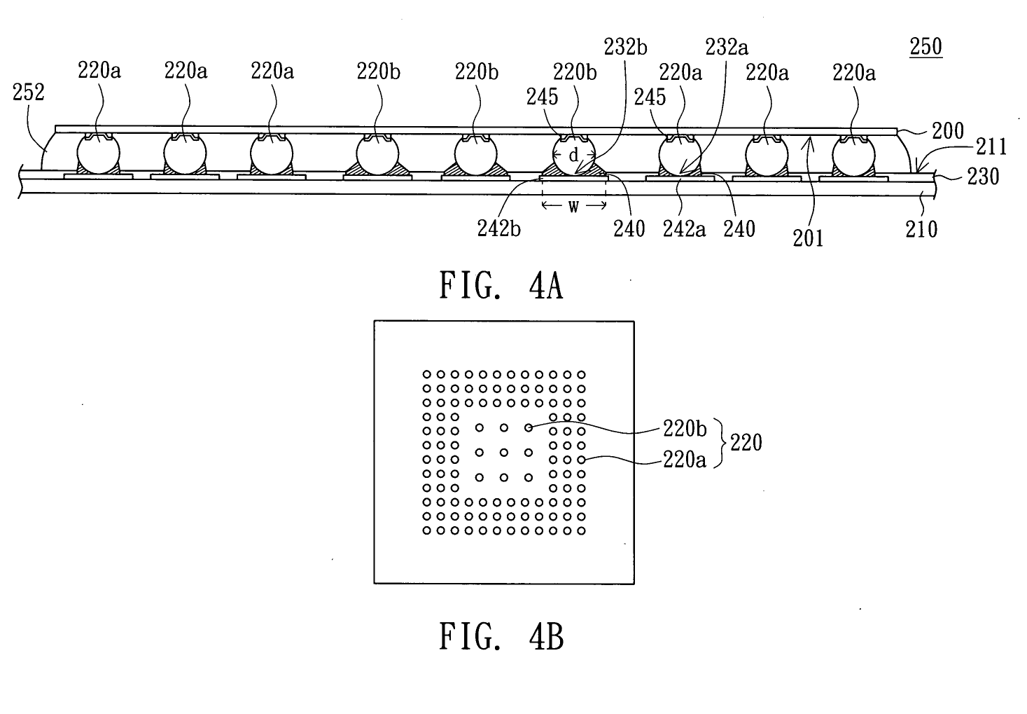

Referring to FIG. 4A and FIG. 4B. FIG. 4A is a side view of a package structure according to a first preferred embodiment of the invention. FIG. 4B is a bottom view of a chip of FIG. 4A. In FIG. 4A, the package structure 250 includes a chip 200, a substrate 210 and a plurality of solders 240. The chip 200 includes a number of first bumps 220a and second bumps 220b. The chip 200 further includes a number of under bump metallurgy (UBM) layers 245 disposed between the first bumps 220a and the active surface 201 of the chip 200 and between the second bumps 220b and the active surface 201 of the chip 200. The first bumps 220a are distributed around the active surface 201 of the chip 200. The second bumps 220b are distributed at the central region of the active surface 201 of the chip 200. The first bumps 220a are more intensively distributed than the second bumps 220b as shown in FIG. 4B.

Referring to FIG. 4A, the substrate 210 includes a number of first pads 242a and second pads 242b, and a solder resistor layer 230. The solder resistor layer 230 is coated on the surface 211 of the substrate 210. The solder resistor layer 230 has a number of first openings 232a and second openings 232b. The first openings 232a are for exposing the first pads 242a. The second openings 232b are for exposing the second pads 242b. The first pads 242a correspond to the first bumps 220a and are disposed on the surface 211 of the substrate 210. The second pads 242b correspond to the second bumps 220b and are disposed on the surface 211 of the substrate 210. The ratios of the width w of the second openings 232b to the diameter d of the second bumps 220b range between 1 and 1.5. In the present preferred embodiment of the invention, the ratio of the width w of the opening 232b to the diameter d of the bump 220b is exemplified by 1.5. Furthermore, the solders 240 are disposed in the first openings 232a and the second openings 232b. The first bumps 220a, the first pads 242a and the solders 240 corresponding to the first pads 242a are soldered together, and so are the second bumps 220b, the second pads 242b and the solders 240 corresponding to the second pads 242b soldered together for electrically connecting the chip 200 and the substrate 210.

The package structure 250 further includes a molding compound 252 disposed between the active surface 201 of the chip 200 and the surface 211 of the substrate 210 for covering the first bumps 220a, the second bumps 220b, the first pads 242a and the second pads 242b which are soldered and electrically connected together. The material of the solders 240, the first bumps 220a and the second bumps 220b includes lead-free alloy, solder alloy or high-lead alloy. However, the material of the solders 240, the first bumps 220a and the second bumps 220b is not for limiting the scope of the technology of the invention.

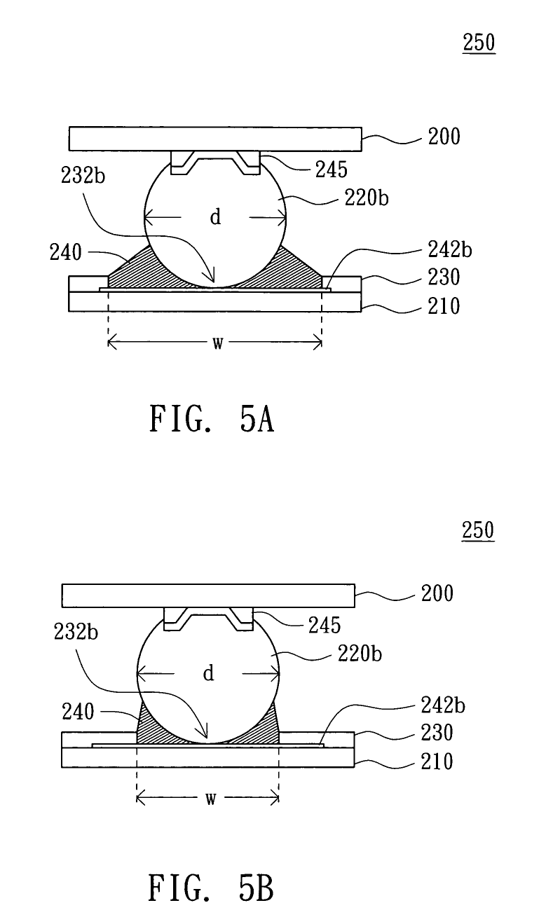

Referring to FIG. 5A, a partial enlargement of a second bump of FIG. 4A is shown. In FIG. 5A, the ratios of the width w of the second openings 232b to the diameter d of the second bumps 220b are 1.5. Therefore, the second openings 232b can accommodate more amount of solder 240, the solders 240 can be disposed on the lateral sides of the second bumps 220b and firmly cover the second bumps 220b. After the second bumps 220b and the solders 240 are soldered together, the second bumps 220b and the solders 240 form a firm chamfered structure illustrated in FIG. 5A.

Referring to FIG. 5B, a diagram illustrating the ratio of the width w to the diameter d of FIG. 5A is 1 is shown. As shown in FIG. 5B, if the ratios of the width w of the second openings 232b to the diameter d of the second bumps are 1, the solders 240 can be disposed on the lateral sides of the second bumps 220b and firmly cover the second bumps 220b, such that the second bumps 220b and the solders 240 are soldered together to form a cylinder structure as illustrated in FIG. 5B. No matter the second bumps 220b and the solders 240 are soldered together to form a chamfered structure or a cylinder structure, the structure protects the second bumps 220b and enhances the bond between the second bumps 220b and the substrate 210. Therefore, the contact points between the second bumps 220b and the substrate 210 are prevented from being damaged due to the difference in the coefficient of thermal expansion between the chip and the substrate when the chip and the substrate are heated and expand. However, any package structures whose ratios of the width w of the second openings 232b to the diameter d of the second bumps 220b range between 1 and 1.5 are capable of fastening the contact points. The chamfered structure and the cylinder structure disclosed in the present preferred embodiment of the invention are not for limiting the scope of technology of the invention.

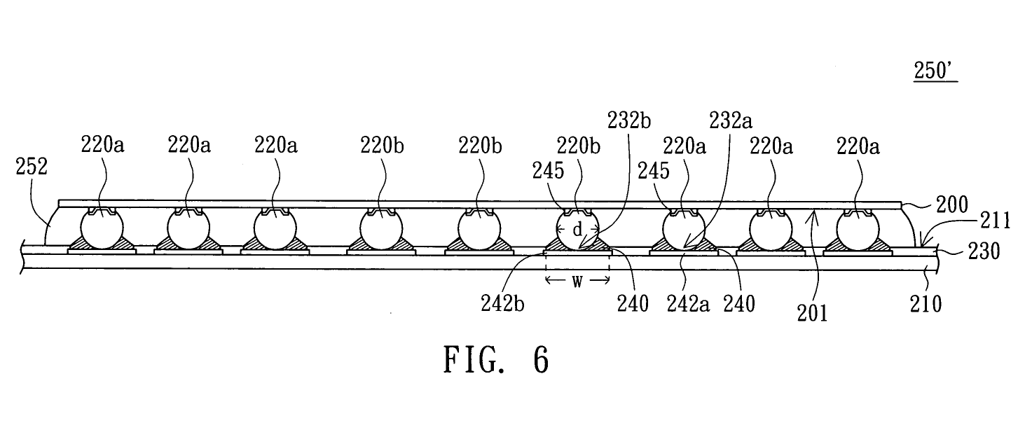

Referring to FIG. 6, a diagram illustrating the ratio of the width of the first opening to the diameter of the first bump of FIG. 4A is 1 is shown. Despite the present preferred embodiment of the invention is exemplified by the ratios of the width w of the second openings 232b to the diameter d of the second bumps 220b being between 1 and 1.5 , however, the ratios of the width w of the first openings 232a to the diameter d of the first bumps 220a can be between 1 and 1.5 as well. As shown in FIG. 6, in another package structure 250′, both the ratios of the diameter of the first bumps 220a to the width w of the first openings 232a and the ratios of the diameter of the second bumps 220b to the width w of the second openings 232b are 1.5, such that the first bumps 220a and the second bumps 220b form a chamfered structure with the solders 240. The chamfered structure enables a stronger bond between the first bumps 220a and the substrate 210 and between the second bumps 220b and the substrate 210, avoiding the contact points between the first bumps 220a and the substrate 210 as well as the contact points between 5 the second bumps 220b and the substrate 210 being damaged. That is, in the package structure 250′, the contact points between the first bumps 220a and the substrate 210 as well as the contact points between the second bumps 220b and the substrate 210 are firm and stable.

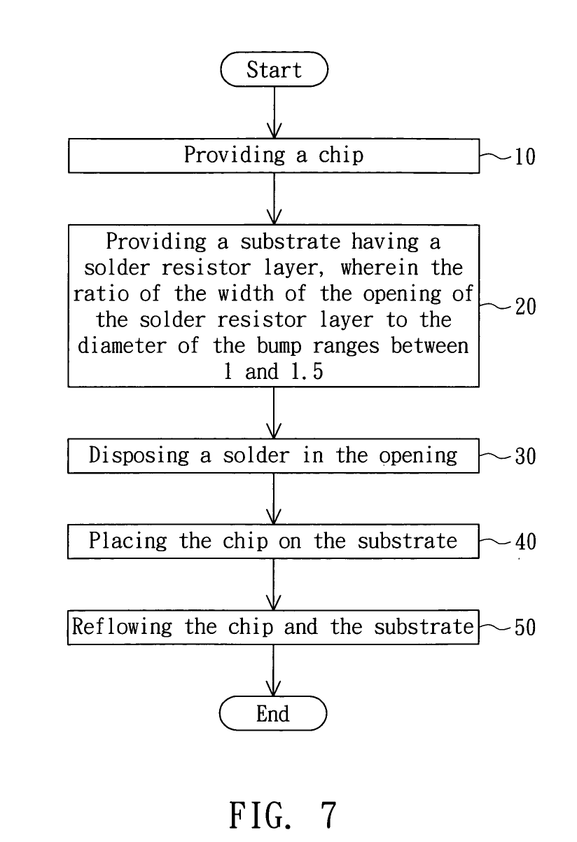

Referring to both FIG. 5A and FIG. 7. FIG. 7 is a flowchart of a method of manufacturing a package structure according to a first preferred embodiment of the invention. At first, the method begins at step 10, a chip including a bump is provided. The chip and the bump are exemplified by the chip 200 and the second bump 220b. Next, proceed to step 20, a substrate including a pad and a solder resistor layer is provided. The substrate, the pad and the solder resistor layer are exemplified by the substrate 210, the second pad 242b and the solder resistor layer 230. The second pad 242b is disposed on the surface 211 of the substrate 210 and corresponds to the second bump 220b. The solder resistor layer 230 is disposed on the surface 211 of the substrate 210. The solder resistor layer 230 has a second opening 232b for exposing the second pads 242b. The ratio of the width w of the second Opening 232b to the diameter d of the second bump 220b ranges between 1 and 1.5. Then, proceed to step 30, a solder is disposed in the second opening 232b. The solder is exemplified by the solder 240. Next, proceed to step 40, the chip 200 is placed on the substrate 210, and the second bump 220b corresponds to the second opening 232b. Then, proceed to step 50, the chip 200 and the substrate 210 are reflown to solder the second bump 220b, the solder 240 and the second pad 242b.

### Second Embodiment

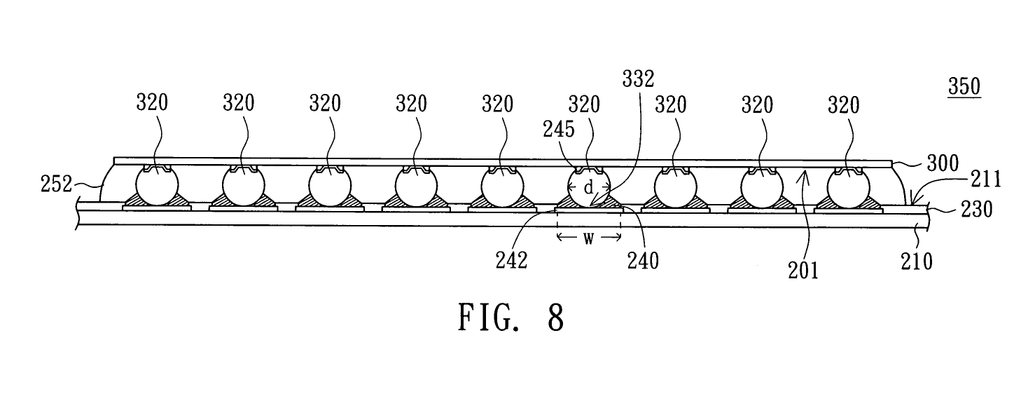

Referring to FIG. 8, a side view of a package structure according to a second preferred embodiment of the invention is shown. The package structure 350 of the present preferred embodiment of the invention differs with the package structure 250 of the first preferred embodiment in the distribution of the bump 320 on the active surface 201 of the chip 300. As for other common components, the same numeric designations are retained and are not repeated here. In the present preferred embodiment of the invention, a number of bumps 320 are equally spaced and disposed on the active surface 201 of the chip 300. The ratios of the width w of the openings 332 corresponding to the bumps 320 disposed on the chip 300 to the diameter d of the bumps are all equal to 1.5. The openings 332 are for exposing the pads 242 and correspond to the bump 320 disposed on the surface 211 of the substrate 210. After the solders 240 are disposed in the openings 332, the solders 240 are disposed on the lateral sides of the bump 320 and firmly cover the bump 320, such that the bond between the bumps 320 and the substrate 210 is enhanced and that the contact points between the bumps 320 and the substrate are less likely to be damaged. In the present preferred embodiment of the invention, the ratio of the width w of the opening to the diameter d of the bump is exemplified by 1.5. However, the invention is not limited thereto. Any package structures whose ratios of the width w of the openings 332 to the diameter d of the bumps 320 ranging between 1 and 1.5 can achieve the same effect as disclosed above.

A package structure is disclosed in the above preferred embodiments of the invention. In the solder resistor layer, the ratio of the width of the opening to the diameter of the bump ranges between 1 and 1.5. The opening is able to accommodate more amount of solder. The solders are disposed on the lateral sides of the bumps and cover up the bumps, such that the solders and the bumps form a cylinder structure, a chamfered structure or a structure of other shapes so as to enhance the bond between the bumps and the substrate, prevent the contact point between the bumps and the substrate from being damaged by the stress and prolong the lifespan of the package structure.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A package structure, comprising:
a chip, comprising:
a plurality of first bumps distributed around the surface of the chip; and
a plurality of second bumps distributed at the central region the surface of the chip, wherein the first bumps are more intensively disposed than the second bumps;
a substrate, comprising:
a plurality of first pads, being corresponding to the first bumps and disposed on the surface of the substrate;
a plurality of second pads, being corresponding to the second bumps and disposed on the surface of the substrate;
a solder resistor layer disposed on the surface of the substrate, wherein the solder resistor layer has a plurality of first openings and second openings, the first openings are for exposing the first pads, the second openings are for exposing the second pads, the ratios of the width of the second openings to the diameter of the second bumps range between 1 and 1.5; and
a plurality of solders disposed in the first openings and the second openings, wherein the solders, the first bumps and the first pads corresponding to the first bumps are welded together, and so are the solders, the second bumps and the second pads corresponding to the second bumps welded together for electrically connecting the chip and the substrate.

2. The package structure according to claim 1, wherein the ratios of the width of the first openings to the diameter of the first bumps range between 1 and 1.5.

3. The package structure according to claim 1, wherein the solders cover the bumps, such that the bumps and the solders form a cylinder structure.

4. The package structure according to claim 1, wherein the solders cover the bumps, such that the bumps and the solders form a chamfered structure.

5. The package structure according to claim 1, wherein the chip further has a plurality of under bump metallurgy (UBM) layers disposed between the surface of the chip and the first bumps or the second bumps.

6. The package structure according to claim 1, wherein the material of the solders is lead-free alloy, solder alloy or high-lead alloy.

7. The package structure according to claim 1, wherein the material of the bump is lead-free alloy, solder alloy or high-lead alloy.

8. A package structure, comprising:
a chip, comprising:
a bump disposed on the surface of the chip;
a substrate, comprising:
a pad, being corresponding to the bump and disposed on the surface of the substrate; and
a solder resistor layer disposed on the surface of the substrate, wherein the solder resistor layer has an opening for exposing the pad, the ratio of the width of the opening to the diameter of the bump ranges between 1 and 1.5; and
a solder disposed in the opening and covering around the bump, wherein the solder, the bump and the pad are welded together for electrically connecting the chip and the substrate.

9. The package structure according to claim 8, the solder covers the bump, such that the bump and the solder form a cylinder structure.

10. The package structure according to claim 8, the solder covers the bump, such that the bump and the solder form a chamfered structure.

11. The package structure according to claim 8, wherein the chip further has an under bump metallurgy (UBM) layer disposed between the surface of the chip and the bump.

12. The package structure according to claim 8, wherein the material of the solder is a lead-free alloy, a solder alloy or a high-lead alloy.

13. The package structure according to claim 8, wherein the material of the bump is a lead-free alloy, a solder alloy or a high-lead alloy.

14. A method of manufacturing a package structure, the method comprising:
providing a chip, wherein the chip comprises a bump;
providing a substrate, wherein the substrate comprises a pad and a solder resistor layer, the pad corresponds to the bump and is disposed on the surface of the substrate, the solder resistor layer is disposed on the surface of the substrate, the solder resistor layer has an opening for exposing the pad, the ratio of the width of the opening to the diameter of the bump ranges between 1 and 1.5;
disposing a solder in the opening;
placing the chip on the substrate, wherein the bump corresponds to the opening; and
reflowing the chip and the substrate to solder the bump, the solder and the pad.

15. The method according to claim 14, wherein the material of the solder is a lead-free alloy, a solder alloy or a high-lead alloy.

16. The method according to claim 14, wherein the material of the bump is a lead-free alloy, a solder alloy or a high-lead alloy.
